(19) United States
(12) Patent Application Publication
(10) Pub. No.: US 2014/0127890 A1
(43) Pub. Date: May 8, 2014

(54) METHOD AND APPARATUS FOR FABRICATING FREE-STANDING GROUP III NITRIDE CRYSTALS

(71) Applicant: Maxim Blashenkov, St. Petersburg (RU)

(72) Inventor: Maxim Blashenkov, St. Petersburg (RU)

(73) Assignee: "PERFECT CRYSTALS" LIMITED LIABILITY COMPANY, St. Petersburg (RU)

(21) Appl. No.: 14/122,703

(22) PCT Filed: May 31, 2012
(86) PCT No.: PCT/EP2012/060227

§ 371 Date: Nov. 27, 2013

Related U.S. Application Data
(60) Provisional application No. 61/491,401, filed on May 31, 2011.

(51) Int. Cl. H01L 21/02

(52) U.S. Cl. CPC H01L 21/02664; H01L 21/02458; H01L 21/02513; H01L 21/0254; H01L 21/02598; H01L 21/0262
USPC 438/507

(57) ABSTRACT

The method for fabricating a free-standing group III nitride plate (6) comprises the steps of: growing a first group III nitride layer (2) on a foreign growth substrate (1); treating the first group III nitride layer (2) so as to make it porous; growing at a growth temperature within a growth reactor (7) a second group III nitride layer (4) on the first group III nitride layer (2); and separating the second group III nitride layer (4) from the growth substrate (1) so as to form a free-standing group III nitride plate (6). According to the present invention, the step of separating the second group III nitride layer (4) from the growth substrate (6) is performed at the growth temperature and within a growth reactor (7), and comprises selective chemical etching of the porous first group III nitride layer (2).

### FIELD OF THE INVENTION

The present invention relates, in general, to methods and apparatuses for fabricating free-standing group III nitride crystals. The present invention is focused on a method for fabricating a free-standing group III nitride crystal, the method comprising depositing a high-quality quasi-bulk group III nitride single crystal layer on a foreign growth substrate and separating the so formed nitride crystal from the foreign substrate. The present invention is also focused on an apparatus for such method for fabrication.

### BACKGROUND OF THE INVENTION

Due to the many advantageous properties thereof, nitrides of group III metals, i.e. the so called III-nitrides which can also be denoted by the general formula “A3N”, form an important group of semiconductor materials for electronic and optoelectronic applications. As one example, Gallium Nitride (GaN) in its many variations has become one of the most important semiconductor materials for optoelectronic devices such as high brightness Light Emitting Diodes (LEDs) for lighting applications.

Nitride-based devices are typically grown epitaxially as layered structures on substrates. In the case of heteroepitaxy, i.e. when the substrate is of different material than the epitaxially grown crystal, the differences in thermal expansion coefficients and lattice constants between the hetero-substrate and grown A3N plate lead to stress generation at the layer interface area, particularly during the change of the growth temperature or cooling down of the grown structure from the growth temperature. These stresses result in high density of different defects like pits and sometimes even cracks.

Thus, as well-known in the art, in order to avoid such undesired effects due to the different lattice constants and thermal expansion coefficients between the substrate and the device layers grown on it, a growth substrate should most preferably be formed of the same material as the device layers. However, unavailability of high quality, preferably stand-alone III-nitride templates is a well-known problem in this field, having compelled the device manufacturers to use foreign substrates. As an example, common examples of foreign substrate materials for GaN-based devices are sapphire and silicon carbide.

Several techniques for fabricating free-standing group III nitride substrates have been proposed. Those techniques typically include combination of growth steps, mask deposition, and finally removal of the initial growth substrate. Standard horizontal or vertical CVD reactors are commonly used. Generally, such substrates can be produced by depositing a thick layer of a group III nitride, typically having a thickness of several hundreds of micrometers, on a foreign substrate such as sapphire, Al2O3, SiC, Si, etc., and subsequently separating the foreign substrate from the deposited nitride layer(s). Substrate removal can be accomplished in various manners including mechanical grinding, laser lift-off, etching, etc. However, this conventional approach has several limitations. III-nitride deposition process necessitates high temperatures (typically 1000° C. to 1100° C.). During cooling down from the growth temperature to room temperature, the III-nitride film undergoes a biaxial stress caused by the large difference between the thermal-expansion coefficients of the nitride crystal and the substrate material. This stress can cause cracking, bowing, generation of crystal defects, and other adverse effects.

In addition to direct deposition of a thick nitride layer on a foreign substrate, also well-known are several techniques wherein an intermediate nitride layer is first formed on a foreign substrate and treated so as to form a porous nitride layer, e.g. by UV assisted electrochemical etching. A thick nitride crystal layer is then grown on the porous intermediate layer. Finally, the thick nitride layer is separated from the substrate along the porous intermediate layer. As an example, US 2007/0082465 Al discloses a method for producing a free-standing GaN substrate, wherein the porous intermediate layer is formed by providing an GaN layer in a reactor, and supplying HCl and NH3 gases into the reactor to treat the GaN layer. The separation of the substrate from the thick GaN layer is facilitated by cracks or fractures in the porous layer caused by thermal stresses during cooling down the deposited structure from the deposition temperature. The main drawback of this technique is the limited control of the separation process.

Due to said problems of the prior art approaches, there is still a continuous and intense need in the market for effective and well-controlled methods and apparatuses for fabricating stand-alone, i.e. free-standing high quality group III nitride crystals.

### PURPOSE OF THE INVENTION

The purpose of the present invention is to provide solutions for the above need.

### SUMMARY OF THE INVENTION

The present invention is focused on a method for fabricating a high-quality free-standing group III nitride plate, i.e. a crystal in the form of a wafer-like plate, having low stresses and low defect density. The group III nitride can be e.g. gallium nitride GaN.

The method comprises the steps of: growing a first group III nitride layer on a foreign growth substrate; treating the first group III nitride layer so as to make it porous; growing at a growth temperature within a growth reactor a second group III nitride layer on the first group III nitride layer; and separating the second group III nitride layer from the growth substrate so as to form a free-standing group III nitride plate.

Said steps of growing can be performed using any known Chemical Vapor Deposition (CVD) process, including but not limited to metal-organic CVD and Hydrid Vapor Epitaxy HVPE. Similarly, in the step of making the first group III nitride porous, any known method suitable for treating group III nitride so as to make it porous can be used. One possible alternative is electrochemical etching.

The foreign substrate can be of any material suitable for CVD deposition of group III nitrides, and different from the nitride to be grown. Widely used materials are e.g. sapphire and silicon carbide.

The initial layer, i.e. the first group III nitride layer is a buffer layer between the foreign growth substrate preferably thin with a thickness below 10 μm. In any case, the thickness should be so low that no stress-induced defects occur in this layer. The thickness thereof can be even as low as e.g. 300 nm. In general, in growing the first group III nitride layer, processes and principles as such known in the art can be used.

The second group III nitride layer is the layer finally forming the actual free-standing plate. Thus, its thickness must provide sufficient mechanical strength and keep the plate flat after removal of the growth substrate. For example, for a wafer having a size of 2 inches, the suitable thickness can be e.g. about 500 μm. If higher thickness is grown, it may be possible to slice the completed plate into two or more thinner wafers.

Treating the first group III nitride layer so as to make it porous means that open pores, i.e. pores which are open to the surroundings of the first group III nitride layer are formed in the nitride. Making the layer that way porous has several effects. For example, it weakens the nitride material mechanically, thereby facilitating the separation of the second group III nitride layer from the growth substrate along the porous layer; stimulates stress relaxation in the first group III nitride layer itself and, consequently, also in the second group III nitride layer grown on it; reduces the propagation of defects (dislocations) into the second group III nitride layer; and prevents cracking of the first group III nitride layer.

According to the present invention, the step of separating the second group III nitride layer from the growth substrate is performed at the growth temperature and within the growth reactor, and comprises selective chemical etching of the porous first group III nitride layer.

Said principle of performing said separation at the growth temperature in the growth reactor provides great advantages. When the second group III nitride is separated from the growth substrate in a high temperature and without first removing the grown sample from the growth reactor, the harmful stress generation due to the different thermal behavior of the substrate and the grown nitride during the decrease of temperature is avoided. As a result, crack-free, low-defect density nitride plate can be produced. Moreover, the selective process can be performed efficiently in situ.

A key feature in the separation of the second group III nitride layer is the selective chemical etching of the porous first group III nitride layer. When etching gases are supplied to the growth reactor, in principle both nitride layers are etched. However, the highly enhanced diffusion of the etching gas molecules into the first group III nitride layer via the pores therein makes this layer to be etched drastically faster than the second group III nitride layer.

Selective chemical etching is preferably continued as long as the buffer layer, i.e. the first group III nitride layer is fully removed, and the second group III nitride layer is thereby separated from the growth substrate. Due to the selectivity of the etching, the second group III nitride layer finally forming the free-standing nitride plate is etched only partially at its top surface. The selectivity can be further enhanced by means of a protective layer of suitable material arranged on top of the second group III nitride layer.

In addition to the selective chemical etching, another process taking place at the high growth temperature and facilitating the removal of the first group III nitride layer is thermal decomposition. The rate of decomposition of the porous nitride under the influence of a high temperature is much faster than that of the solid nitride. The free surface area of the porous nitride in the first group III nitride layer is much larger compared to that of the bulk nitride in the second group III nitride layer. Therefore the porous buffer layer loses nitrogen atoms much faster. Moreover, thermal decomposition of the bulk nitride in the second group III nitride layer can be fully suppressed by supplying ammonia or continuing nitride deposition during the thermal treatment of the porous layer.

By growth temperature is meant in this specification the temperature range used in the steps of growing the second group III nitride layers. Typically this lies around about 1000° C. The temperature in which the selective chemical etching is performed is not required to be exactly within the lower and upper limits of the growth temperature range but may slightly deviate from said range in so far as the temperature is sufficiently low to avoid said harmful stress generation. Preferably, the step of separating selective chemical etching is performed at a temperature which is within ±50° C. from the growth temperature, i.e. is below or exceeds the growth temperature range by no more than 50° C.

In the method of the present invention, in the step of growing at a growth temperature within a growth reactor a first group III nitride layer on a foreign growth substrate comprises, a first group III nitride layer having a plurality of sub-layers may be formed. A multi-layered inner structure of the first nitride layer can help to achieve a smooth and low-defect density surface of this layer acting as the growth surface for the second group III nitride layer.

At least some of the gases used as the growth process gases in the steps of growing the group III nitride layers are preferably used also as etching gases in said selective chemical etching.

According to a second aspect, the present invention is focused on a growth reactor for growing group III nitride layers on a foreign growth substrate. The growth reactor of the present invention comprises a first zone for said growing of group III nitride layers by CVD deposition.

According to the present invention, the growth reactor further comprises a second zone and a gas system for supplying etching gases for selectively etching, in the second zone, a group III nitride layer grown in the first zone.

Thus, in the reactor design of the present invention, in addition to a standard growth zone(s), a special additional zone for selective chemical etching is added. This second zone and the gas system of the growth reactor enable separation of the second group III nitride from the growth substrate at the growth temperature within the growth reactor, so without first removing the grown layer stack from the reactor. This leads to the great advantages as described above in the context of the method aspect of the present invention.

To summarize, the method and the reactor according to the present invention has the following features:

i) The process of plate fabrication includes the following steps: (1) creating a buffer layer with open pores, the layer being made of an A3N material; (2) growing a thick A3N layer on top of said buffer layer; (3) selective chemical etching of the grown nitride layers to remove the buffer layer.

ii) The separation of the thick nitride layer from the growth substrate is performed in situ within the CVD reactor in which the thick nitride layer was grown.

iii) The growth reactor has two main operation zones: (1) a standard growth zone for CVD deposition, and (2) an etching zone for chemical etching. The construction further comprises means to transport the grown crystals from the former zone one to the latter and back.

iv) Said separation is performed in the etching zone and substantially at the growth temperature.

v) In selective chemical etching, the growth process gases, possibly together with some special gases can be used.

### BRIEF DESCRIPTION OF THE DRAWINGS

FIG. 1 schematically depicts a method for fabricating a high-quality A3N single crystal plate according to the present invention.

FIG. 2 schematically depicts a schematic view of a growth reactor according to the present invention.

### DETAILED DESCRIPTION OF THE INVENTION

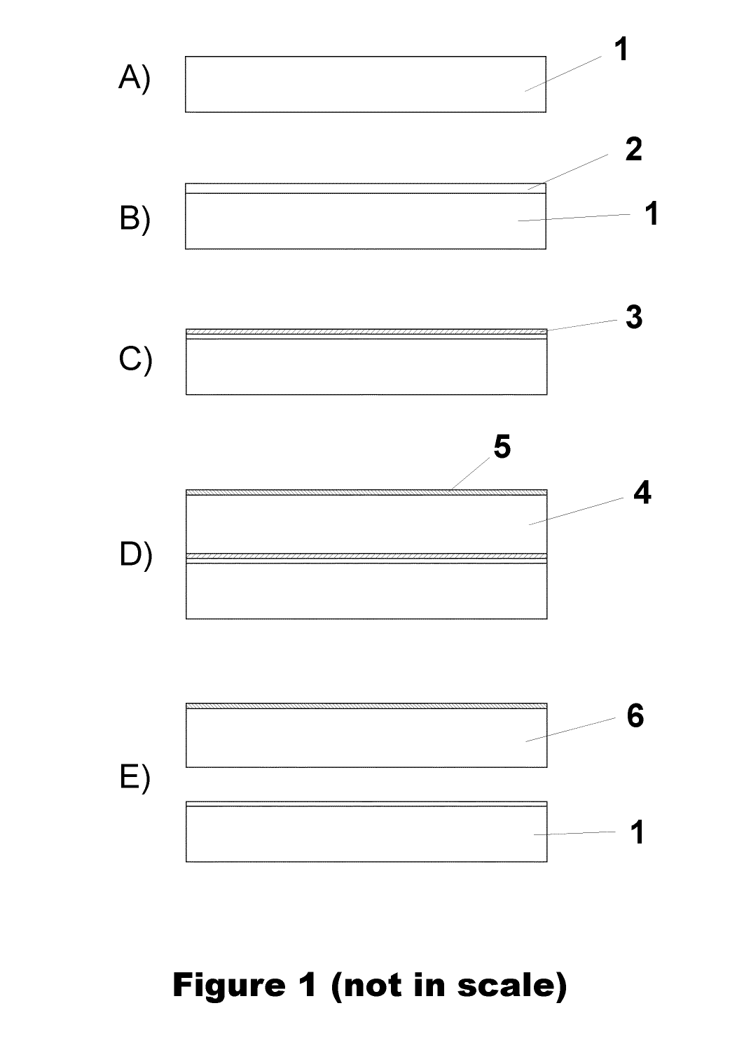

In the process illustrated in FIG. 1, the growth substrate 1 is a hetero-substrate, i.e. it is made from any material suitable for group III nitride growth by CVD but not from the same material as the nitride itself.

First, in step b), an initial A3N layer 2 is deposited by means of CVD. This layer is thin (<10 μm) to avoid defect formation. This layer can also comprise a plurality of layers aimed to provide smooth and defect-free initial A3N surface. Next, in step c), the initial A3N layer is treated so as to make at least a portion 3 of it porous, i.e. having open pores. Any known method for creating a porous layer with open pores can be used.

Then, in step d), growth of a thick group III nitride layer 4 (up to few hundreds μm) is performed on top of the initial nitride layer 2 to form a thick-enough A3N layer capable to keep flat surface after removal of the hetero-substrate. Also this thick A3N layer can comprise a plurality of sub-layers.

As an optional but preferred feature, a protective layer 5 of e.g. SiNx may be formed on the top of the thick group III nitride layer 4.

Next, the temperature of the grown layer stack is kept substantially at the same level as during the growth of the thick nitride layer 4, and etching gases are supplied to etch the nitride layers. The porous portion of the first nitride layer 2 is etched much faster than the second nitride layer 4. The protective layer 5 further increases the selectivity of the etching. This selective chemical etching, possibly together with thermal decomposition of the nitride, leads to complete removal of the porous portion 3 of the first nitride layer. Thereby, the second nitride layer 4 is separated from the growth substrate 1. Thus, a free-standing group III nitride plate 6 is formed. Finally, the plate 6 is cooled down to room temperature and the protective layer 5 thereon is removed.

Due to the separation of the growth substrate 1 from the grown nitride before cooling down the grown nitride plate, thermal stresses in the plate 6 during said cooling down can be kept below critical values, and thus no cracks or other stress-induced defects are formed in the completed nitride plate 6.

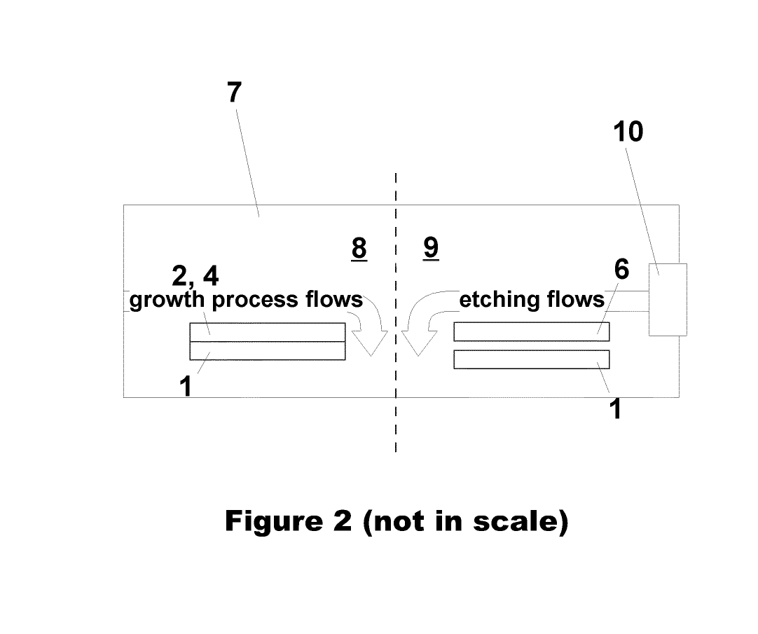

FIG. 2 discloses a schematic view of the novel reactor design. The reactor 7 has two main operation zones. The first is a standard growth zone 8 for CVD deposition. There can also be a plurality of growth zones in the reactor. The second zone 9 is an etching zone for chemical etching of nitride layers 2, 4 grown in the first zone. In operation, the etching zone 9 can be kept at the same temperature as the growth zone 8. The etching zone 9 has a gas supply system 10 for supplying gases for chemical etching of the nitride layers.

In the following, one specific example of the method according to the present invention is presented in more detail.

### EXAMPLE

A 6H-SiC substrate was loaded into an HVPE reactor. The reactor was heated up to 1050° C., and GaN deposition was started by supplying GaCl and NH₃ to the growth zone. The layer was grown to a thickness of approximately 2 microns. After the completion of growth, the reactor was cooled down to the ambient temperature and the substrate was taken out from the reactor and loaded into an electrochemical etching apparatus to form a porous layer on top of the GaN layer. A 4% aqueous solution of hydrofluoric acid was used as an electrolyte, the current density was in the range from 10 to 20 mA/cm², and a standard 250W mercury lamp was used as an UV radiation source. The sample was rinsed in deionised water and solvents, and then blow dried and loaded into the HVPE reactor. The reactor was heated up to 1050° C., and 300 microns of GaN were deposited following standard procedures. On completion of this second GaN layer growth, SiH₄ and NH₃ gases were supplied to the growth chamber to form a protective SiNₓ layer on GaN surface. Here “x” denotes silicon nitride of varying stoichiometry. X is a number typically lying in the range from 0.1 to 1.3. Next, the entire stack with the substrate and the grown nitride layers was transferred to an etching chamber within the same reactor and subjected to etching by hot HCl gas. The HCl gas attacks preferentially the porous layer and leaves bulk GaN layer intact because of faster reactivity of the porous GaN and protective SiNx coating on the top surface. The etching was continued until the porous layer was fully destroyed, thereby leaving a free-standing GaN crystal in the form of a wafer-like plate, after which the reactor was cooled down to the room temperature. As the bond between the base substrate and the GaN layer was destroyed during the selective etching, the wafer did not experience any bowing or cracking during cooling down.

It is clear that the invention is not limited to the above examples and embodiments only. Instead, the embodiments of the present invention may freely vary within the scope of the claims.

1. A method for fabricating a free-standing group III nitride plate, the method comprising the steps of:
growing a first group III nitride layer on a foreign growth substrate;
treating the first group III nitride layer so as to make it porous;
growing at a growth temperature within a growth reactor a second group III nitride layer on the first group III nitride layer; and separating the second group III nitride layer from the growth substrate so as to form a free-standing group III nitride plate;
characterized in that the step of separating the second group III nitride layer from the growth substrate is performed at the growth temperature and within the growth reactor, and comprises selective chemical etching of the porous first group III nitride layer.

2. A method as defined in claim 1, wherein in the selective chemical etching step, gases used in the steps of growing the group III nitride layers are used as etching gases.

3. A method as defined in claim 1 wherein, in the step of growing a first group III nitride layer on a foreign growth substrate, a first group III nitride layer having a plurality of sub-layers is formed.

4. A growth reactor for growing group III nitride layers on a foreign grown substrate, the growth reactor comprising a first zone for said growing of group III nitride layers by CVD deposition, characterized in that the growth reactor further comprises a second zone and a gas system for supplying etching gases for selectively etching, in the second zone, a group III nitride layer grown in the first zone.

5. A method as defined in claim 2 wherein, in the step of growing a first group III nitride layer on a foreign growth substrate, a first group III nitride layer having a plurality of sub-layers is formed.
